(19) United States
(12) Patent Application Publication
(10) Pub. No.: US 2026/0041007 A1
(43) Pub. Date: Feb. 5, 2026

(54) DIE SIDE INTERCONNECT

(71) Applicant: Micron Technology, Inc., Boise, ID (US)

(72) Inventors: Owen R. Fay, Meridian, ID (US); Brandon P. Wirz, Boise, ID (US); Andrew M. Bayless, Boise, ID (US)

(21) Appl. No.: 19/280,842

(22) Filed: Jul. 25, 2025

Related U.S. Application Data
(60) Provisional application No. 63/677,303, filed on Jul. 30, 2024.

(51) Int. Cl. H01L 25/18; H01L 21/56; H01L 21/78; H01L 23/00; H01L 25/00; H01L 25/065; H10D 80/00; H10D 80/30

(52) U.S. Cl. CPC H01L 25/18; H01L 21/561; H01L 21/78; H01L 24/02; H01L 24/08; H01L 24/13; H01L 24/16; H01L 24/32; H01L 24/73; H01L 25/0655; H01L 25/50; H10D 80/00; H10D 80/30; H01L 24/80; H01L 2224/02372; H01L 2224/02381; H01L 2224/024; H01L 2224/08146; H01L 2224/13109; H01L 2224/13111; H01L 2224/13139; H01L 2224/13147; H01L 2224/13155; H01L 2224/16146; H01L 2224/32137; H01L 2224/73253; H01L 2224/80895; H01L 2224/80896

(57) ABSTRACT

Methods, systems, and devices for die side interconnect are described. A semiconductor assembly may include a stack of first dies (e.g., memory dies) coupled with a second die (e.g., a logic die) using a sideways architecture. For example, the semiconductor assembly may include multiple first dies, where a top surface of one the first dies is coupled with a bottom surface of another of the first dies to form the stack. The first dies each have a side surface coupled with an upper surface of the second die. The first dies each include a conductive via extending from the top surface of the respective first die at least partially towards the bottom surface of the respective first die. The first dies each include a redistribution layer coupled with the conductive via and extending parallel with the top surface of the respective first die.

### CROSS REFERENCE

The present Application for patent claims priority to U.S. Patent Application No. 63/677,303 by Fay et al., entitled “DIE SIDE INTERCONNECT,” filed Jul. 30, 2024, which is assigned to the assignee hereof, and which is expressly incorporated by reference in its entirety herein.

### TECHNICAL FIELD

The following relates to one or more systems for memory, including die side interconnect.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports die side interconnect in accordance with examples as disclosed herein.

FIG. 2 shows an example of a semiconductor assembly that supports die side interconnect in accordance with examples as disclosed herein.

FIGS. 3A, 3B, 3C, 3D, 3E, 3F, 3G, and 3H show examples of processing steps support die side interconnect in accordance with examples as disclosed herein.

FIG. 4 shows a flowchart illustrating a method or methods that support die side interconnect in accordance with examples as disclosed herein.

### DETAILED DESCRIPTION

Some semiconductor assemblies may include one or more semiconductor dies stacked in a vertical architecture. For example, a semiconductor assembly may include one or more memory dies (e.g., a stack of memory dies) stacked above a logic die. However, implementing a stack of memory dies above the logic die in a vertical architecture may cause connectivity issues for coupling one or more upper memory dies of the stack with the logic die or heat dissipation issues within the stack. For example, to couple the one or more upper memory dies of the stack with the logic die, the memory dies of the stack may implement various conductive structures extending within the memory dies for communicating signaling, dissipating heat within the stack, or transmitting power between the logic die and the memory dies. However, implementing the various conductive structures may be associated with relatively high spatial consumption of the internal architecture of the memory dies. In other examples, the memory dies may not implement the various conductive structures to conserve spatial consumption of the internal architecture of the memory dies. However, not implementing the various conductive structures may cause relatively low connectivity between the memory dies and the logic die or relatively low heat dissipation within the stack.

In accordance with examples as described herein, a semiconductor assembly may include one or more stacks of first dies (e.g., memory dies) coupled with a second die (e.g., a logic die) via a sideways architecture. For example, the semiconductor assembly may include a stack of first dies (e.g., a stack of memory dies) in which side surfaces of the first dies are coupled with a top surface of the second die, such that the semiconductor assembly may implement the stack of first dies at a sideways orientation (e.g., at a 90° orientation, a perpendicular orientation) relative to a normal orientation (e.g., a 0° orientation) of the second die. In some examples, the first dies may be formed (e.g., at the normal orientation) to include one or more conductive vias (e.g., through silicon vias (TSVs)) extending vertically (e.g., relative to the normal orientation) at least partially through the first dies (e.g., from a top surface of each first die towards a bottom surface of each first die), and one or more redistribution layers (RDLs) extending horizontally (e.g., relative to the normal orientation) across the first dies (e.g., parallel to the top surface of each first die). After bonding and dicing the first dies to form stacks of the first dies, the stacks may be rotated to the sideways orientation (e.g., such that the conductive vias extend parallel to the top surface of the second die) and the conductive vias of the first dies may be exposed. Then, the exposed conductive vias may be bonded with the top surface of the second die, such that the stacks may be coupled with the second die at the sideways orientation. Implementing the sideways architecture within the semiconductor assembly may increase connectivity between the first dies and the second die, decrease heat dissipation issues within the stacks, and improve power delivery from the second die to the stacks, among other advantages. Additionally, forming the sideways architecture may implement manufacturing techniques that allow for more flexibility (e.g., greater die misalignment tolerance) during forming the semiconductor assembly.

In addition to applicability in memory systems as described herein, techniques for die side interconnect may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by increasing connectivity within a semiconductor assembly using a sideways architecture, which may decrease processing or latency times, improve response times, or otherwise improve user experience, among other benefits.

In addition to applicability in memory systems as described herein, techniques for die side interconnect may be generally implemented to support increased connectivity of electronic systems. As the use of systems relying on interconnected electronic devices increases, the connectivity of these electronic devices becomes an increasingly relevant factor for the operations of the system. For example, delays associated with signals communicated between devices may become increasingly relevant as critical systems come to rely more on connectivity, as a system uses larger quantities of interconnected devices, or if the quantity and the complexity of signals communicated between devices increases. Implementing the techniques described herein may support techniques for increased connectivity in electronic systems by implementing a sideways architecture within a semiconductor assembly, thereby allowing first dies (e.g., memory dies) of the semiconductor assembly to leverage conductive structures for increasing connectivity to a second die (e.g., a logic die), which may improve signaling, heat dissipation, and power delivery within the semiconductor assembly, among other benefits.

Features of the disclosure are illustrated and described in the context of systems and architectures. Features of the disclosure are further illustrated and described in the context of semiconductor assemblies, processing steps, and flowcharts.

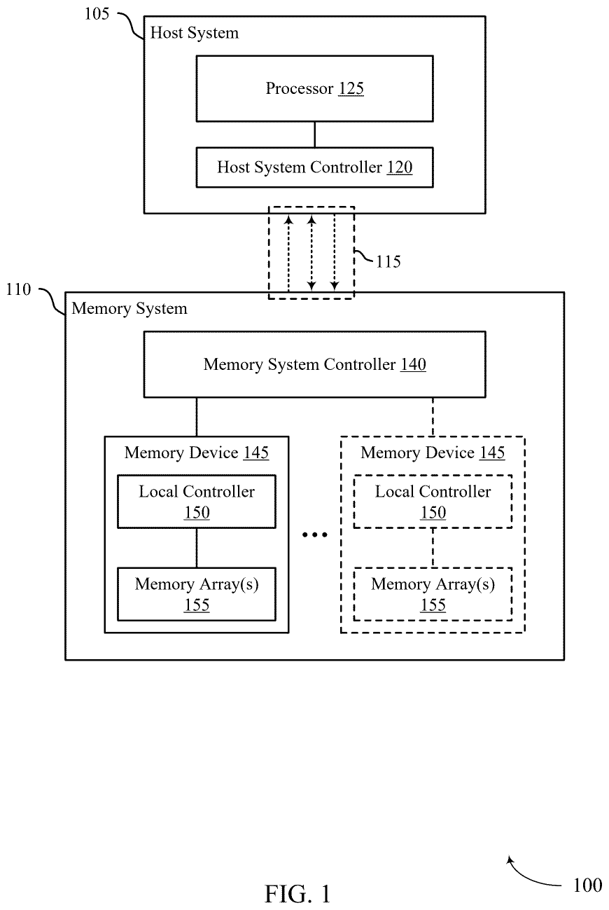

FIG. 1 illustrates an example of a system 100 that supports die side interconnect in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), a system in package, or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

The host system 105 may include one or more components (e.g., circuitry, processing circuitry, one or more processing components) that use memory to execute processes, any one or more of which may be referred to as or be included in a processor 125. The processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. The processor 125 may be an example of a central processing unit (CPU), a graphics processing unit (GPU), a general-purpose GPU (GPGPU), or an SoC or a component thereof, among other examples.

The host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating the memory system 110, such as write commands, read commands, configuration signaling or other operational signaling. In some examples, the host system controller 120, or associated functions described herein, may be implemented by or be part of the processor 125. For example, a host system controller 120 may be hardware, instructions (e.g., software, firmware), or some combination thereof implemented by the processor 125 or other component of the host system 105. In various examples, a host system 105 or a host system controller 120 may be referred to as a host.

The memory system 110 provides physical memory locations (e.g., addresses) that may be used or referenced by the system 100. The memory system 110 may include a memory system controller 140 and one or more memory devices 145 (e.g., memory packages, memory dies, memory chips) operable to store data. The memory system 110 may be configurable for operations with different types of host systems 105, and may respond to commands from the host system 105 (e.g., from a host system controller 120). For example, the memory system 110 (e.g., a memory system controller 140) may receive a write command indicating that the memory system 110 is to store data received from the host system 105, or receive a read command indicating that the memory system 110 is to provide data stored in a memory device 145 to the host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of the memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with the host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 and one or more memory arrays 155. A memory array 155 may be a collection of memory cells (e.g., a two-dimensional array, a three-dimensional array), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

In accordance with examples as described herein, a system 100, or portion thereof, may include a semiconductor assembly, which may include one or more stacks of first dies (e.g., memory dies) coupled with a second die (e.g., a logic die) via a sideways architecture. For example, the semiconductor assembly may include a stack of first dies (e.g., a stack of memory dies) in which side surfaces of the first dies are coupled with a top surface of the second die, such that the semiconductor assembly may implement the stack of first dies at a sideways orientation (e.g., at a 90° orientation, a perpendicular orientation) relative to a normal orientation (e.g., a 0° orientation) of the second die. In some examples, the first dies may be formed (e.g., at the normal orientation) to include one or more conductive vias (e.g., through silicon vias (TSVs)) extending vertically (e.g., relative to the normal orientation) at least partially through the first dies (e.g., from a top surface of each first die towards a bottom surface of each first die), and one or more redistribution layers (RDLs) extending horizontally (e.g., relative to the normal orientation) across the first dies (e.g., parallel to the top surface of each first die). After bonding and dicing the first dies to form stacks of the first dies, the stacks may be rotated to the sideways orientation (e.g., such that the conductive vias extend parallel to the top surface of the second die) and the conductive vias of the first dies may be exposed. Then, the exposed conductive vias may be bonded with the top surface of the second die, such that the stacks may be coupled with the second die at the sideways orientation. Implementing the sideways architecture within the semiconductor assembly may increase connectivity between the first dies and the second die, decrease heat dissipation issues within the stacks, and improve power delivery from the second die to the stacks, among other advantages. Additionally, forming the sideways architecture may implement manufacturing techniques that allow for more flexibility (e.g., greater die misalignment tolerance) during formation of the semiconductor assembly.

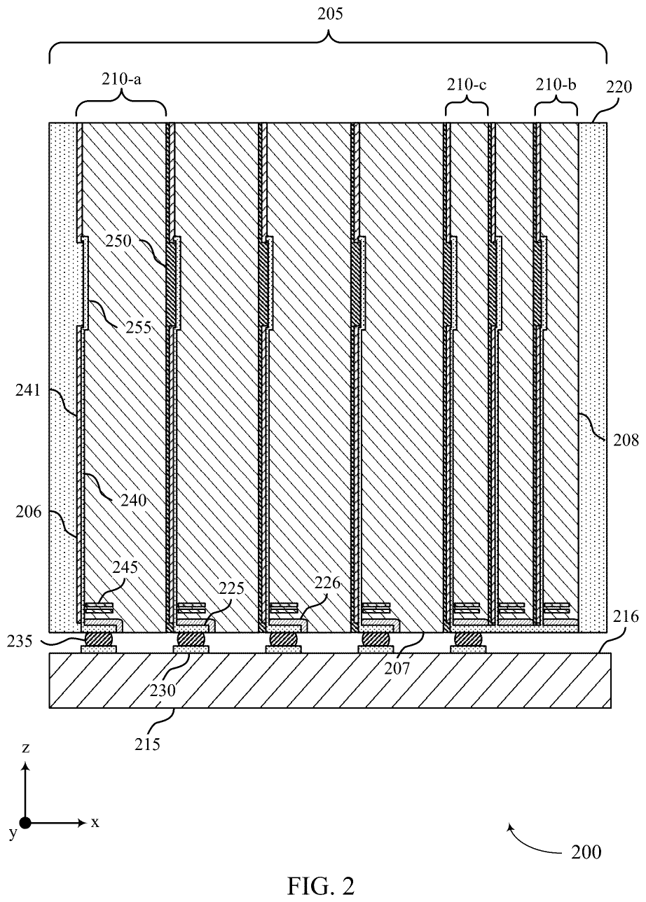

FIG. 2 shows an example of a semiconductor assembly 200 that supports die side interconnect in accordance with examples as disclosed herein. The semiconductor assembly 200 may illustrate aspects of a system, which may be examples of a system 100, as described with reference to FIG. 1. For example, the semiconductor assembly 200 may illustrate an example architecture implemented by the system 100, or one or more component thereof. For illustrative purposes, aspects of the semiconductor assembly 200 may be described with reference to an x-direction, a y-direction, and a z-direction of the illustrated coordinate system. For example, FIG. 2 illustrates the semiconductor assembly 200 from a cross sectional view in an xz-plane, where the semiconductor assembly 200 extends along a distance along the y-direction into the page. The semiconductor assembly 200 may implement a sideways architecture, in which a stack 205 of dies 210 (e.g., first dies, memory dies) may be coupled at a sideways orientation with a die 215 (e.g., a second die, a logic die).

The semiconductor assembly 200 may include one or more stacks 205, where each stack 205 may include a quantity of dies 210. In some examples, the dies 210 may be examples of semiconductor dies including one or more memory arrays and supporting circuitry for the one or more memory arrays. For example, the dies 210 may be examples of DRAM dies each including at least one array of DRAM memory cells. The dies 210 may each include a top surface 206 and a bottom surface 208 each extending along a yz-plane, and a side surface 207 extending along an xy-plane. The dies 210 may be bonded with one another to form the stack 205, such that a top surface 206 of a die 210 (e.g., die 210-b) may be bonded with a bottom surface 208 of another die 210, and a bottom surface 208 of a die 210 (e.g., die 210-a) may be bonded with a top surface 206 of another die 210. In some cases, dies 210 of the stack 205 may include bond films 250 configured to support bonding the top surfaces 206 with the bottom surfaces 208 of the dies 210. For example, a die 210 may implement a bond film 250 on the top surface 206 of the die 210 to bond the top surface 206 with the bottom surface 208 of another die 210. In some cases, the bond film 250 may be a non-conductive film coupled with a bond pad 255 of the die 210.

In some cases, the stack 205 may include an encapsulant material 220 at least partially surrounding the dies 210 of the stack 205. For example, the stack 205 may include a layer of the encapsulant material 220 extending along a yz-plane and having a thickness along the x-direction from the bottom surface 208 of a bottom die 210 (e.g., die 210-b) in the stack 205. Additionally, or alternatively, the stack 205 may include a layer of the encapsulant material 220 extending along a yz-plane and having a thickness along the x-direction from the top surface 206 of a top die 210 (e.g., die 210-a) in the stack 205. The stack 205 may also include encapsulant material 220 in yz-planes at boundaries of the stack 205 into and out of the page along the y-direction, such that the encapsulant material 220 may surround (e.g., enclose) the stack 205 in an xy-plane. In some examples, the encapsulant material 220 may be a spin-on dielectric (SOD) material, a polymer material, an epoxy material, capillary underfill (CUF) material, molded underfill (MUF) material, mold compound, or any combination thereof.

The semiconductor assembly 200 also includes a die 215, which may be an example of a semiconductor die including circuitry associated with operating the dies 210 and facilitating operations of the semiconductor assembly 200. For example, the die 215 may include a complementary metal oxide semiconductor (CMOS) and/or one or more processors of the semiconductor assembly 200. In some such examples, the one or more processors of the die 215 may be configured to control operations of memory arrays within the dies 210, and may be an example of one or more local controllers 150, one or more memory system controllers 140, one or more processors 125, or a combination thereof.

The stack 205 may be bonded with the die 215, such that at least one of the dies 210 (e.g., each die 210) may be coupled with the die 215. The stack 205 may be bonded with the die 215 in a sideways orientation, such that the side surfaces 207 of the dies 210 are coupled with a top surface 216 of the die 215. The sideways orientation of the stack 205 may be relative to a normal orientation of the die 215, such that the stack 205 may be positioned perpendicular to the die 215 (e.g., the top surfaces 206 may be perpendicular to the top surface 216, the side surfaces 207 may be parallel to the top surface 216). For example, the dies 210 of the stack 205 may each have a respective semiconductor substrate (e.g., wafer substrate) oriented in a respective yz-plane, and be bonded with the die 215 that has a semiconductor substrate (e.g., wafer substrate) oriented in an xy-plane. In some cases, the stack 205 may be bonded with the die 215 using conductive vias 225 of one or more of (e.g., each of) the dies 210.

For example, each die 210 may include a conductive via 225 extending at least partially through the die 210 from the top surface 206 of the die 210 toward the bottom surface 208 of the die 210 (e.g., along the x-direction). Further, each conductive via 225 may extend along (e.g., coincident with) the side surface 207 of the respective die 210, and may be associated with bonding the respective die 210 with the die 215. That is, each die 210 may be coupled with the die 215 based on bonding the respective conductive via 225 of the die 210 with a bond pad 230 of the die 215. In some cases, the conductive vias 225 may be an example of a through-silicon via (TSV), and may be formed from copper (e.g., including copper alloys), tungsten (e.g., including tungsten alloys), aluminum (e.g., including aluminum alloys), or any combination thereof, among other conductive materials. In some cases, the conductive vias 225 may be partially surrounded by a dielectric layer 226 including a dielectric material, such as tetraethyl orthosilicate material, oxide material, silicon carbon nitride material, or any combination thereof.

In some cases, the stack 205 may include different types of dies 210. For example, the stack 205 may include a first type of die 210 (e.g., die 210-a, a first type of memory dic) and a second type of die 210 (e.g., die 210-b, die 210-c, a second type of memory die). The first type of die 210 may include the conductive via 225 extending partially through the die 210 from the top surface 206 towards the bottom surface 208 of the die 210. However, the second type of die 210 may include the conductive via 225 extending fully through the dic 210 from the top surface 206 to the bottom surface 208 of the die 210. In some cases, the first type of die 210 may support individually bonding a die 210 with the die 215 using the conductive via 225 of the die 210. However, in some other cases, the second type of die 210 may support group bonding the dies 210 with the die 215 using a single conductive via 225 of a die 210 from each group of dies 210. For example, because the conductive vias 225 may extend fully through the second type of dies 210, the conductive vias 225 of a group of adjacent dies 210 may be coupled such that bonding a single conductive via 225 of the group with the die 215 may communicatively couple each conductive via 225 with the die 215. For example, the die 210-b may be coupled with the die 215 based on a die 210-c being bonded with the die 215, and based on the conductive via 225 associated with the die 210-c being coupled with the conductive via 225 associated with the die 210-b. In some cases, a stack 205 may include the first type of dies 210, the second type of dies 210, or any combination thereof.

In some cases, the stack 205 may be coupled with the die 215 through various bonding techniques. For example, the dies 210 may be bonded with the die 215 based on forming interconnects 235 between the conductive vias 225 of the dies 210 and the bond pads 230 of the die 215. In some implementations, the interconnects 235 may be solder, copper, nickel, tin, silver, indium, or any combination thereof. In other implementations, the interconnects 235 may be optical elements. In some examples, the dies 210 may be bonded with the die 215 based on fusion bonding (e.g., hybrid bonding) of the conductive vias 225 of the dies 210 with the bond pads 230 of the die 215. For example, the bond pads 230 of the die 215 may be conductive structures on the top surface 216 of the die 215, including copper material, tungsten material, aluminum material, or any combination thereof. Thus, a metal material of the conductive vias 225 may be bonded directly with (e.g., fused with) a metal material of the bond pads 230. In some cases, hybrid bonding that includes bonding the conductive vias 225 with the bond pads 230 may also include bonding (e.g., fusing) dielectric material associated with (e.g., around) the conductive vias 225 with dielectric material associated with the bond pads 230.

The dies 210 may include redistribution layers 240 extending across the dies 210. For example, the redistribution layers 240 may extend partially through the dies 210 along the z-direction from the side surface 207 of the dies 210. The redistribution layers 240 may be coupled with the conductive vias 225 based on the redistribution layers 240 including copper material, tungsten material, aluminum material, or any combination thereof. In some cases, the redistribution layers 240 may function as conductive vias within the dies 210 based on the stack 205 being positioned at the sideways orientation relative to the die 215. In some cases, the redistribution layers 240 may form the bond pads 255 at a portion of the dies 210, and may be associated with bonding the dies 210. In some examples, the redistribution layers 240 may be partially covered by a dielectric layer 241, which may include the dielectric material (e.g., the same dielectric material as in the dielectric layer 226) extending along the z-direction across the top surface 206 of the dies 210, and adjacent to the redistribution layers 240 along the x-direction. In some examples, the dies 210 may include a conductive structure 245 adjacent to the conductive vias 225 and the redistribution layers 240. The conductive structure 245 may be an example of a wall of tungsten, such that the conductive structure 245 may include a tungsten material.

In accordance with examples as described herein, the semiconductor assembly 200 may implement the stack 205 of dies 210 at the sideways orientation relative to the die 215. Implementing the stack 205 at the sideways orientation may support improved connectivity between the dies 210 and the die 215. For example, using the conductive vias 225 for bonding the dies 210 with the die 215 may enable the redistribution layers 240 to function as conductive vias extending through the dies 210. In some such examples, the redistribution layers 240 may support increased data path connectivity, improved heat dissipation through the stack 205, and improved power delivery from the die 215.

Although some aspects of the described techniques may include references to a die 215 being a logic die and dies 210 being memory dies, the described techniques for side interconnection are more broadly applicable to heterogeneous semiconductor systems. For example, the techniques may be implemented in accordance with other architectures (e.g., other heterogeneous die architectures) in which dies 210 implement some techniques (e.g., some processing techniques, some memory techniques, some circuitry) and dies 215 implement some other techniques. In some implementations, a semiconductor assembly 200 may be an example of a processor 125, in which dies 210 are configured with first processing circuitry to perform first processing operations, and a die 215 is configured with second processing circuitry to perform second processing operations. In some implementations, a semiconductor assembly 200 may be an example of a memory system 110, in which dies 210 are configured in accordance with one or more memory devices 145, and a die 215 is configured in accordance with a memory system controller 140. In some such examples, one or more first dies 210 may be configured in accordance with a first memory architecture (e.g., a volatile memory architecture), and one or more second dies 210 may be configured in accordance with a second memory architecture (e.g., a non-volatile memory architecture), different than the first memory architecture. In some implementations, a semiconductor assembly 200 may be an example of a system 100, in which dies 210 are configured in accordance with one or more memory systems 110, and a die 215 is configured in accordance with a host system 105 (e.g., a processor 125). Moreover, although some examples refer to a die 215 as being a single die, a die 215 may refer to one or more semiconductor dies, which may include a stack of dies, a reconstructed die (e.g., an assembly of chiplets that may include one or more stacks of dies, one or more adjacent chiplets stacked with a substrate), and other examples. Thus, the described techniques for side interconnection may be implemented for various examples of and configurations of semiconductor assemblies that may benefit from the associated increase in connectivity between dies, improved heat dissipation, improved power delivery, and improved manufacturing flexibility, among other benefits of the described side interconnection.

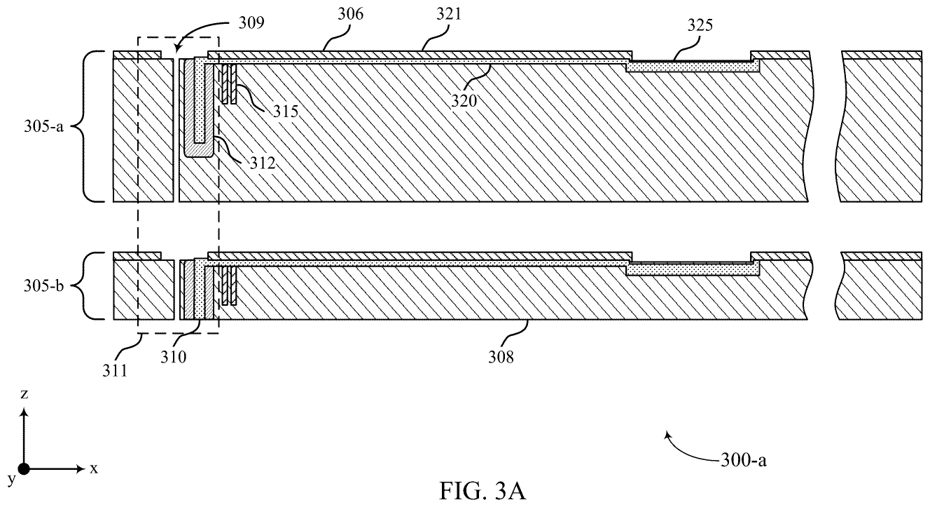

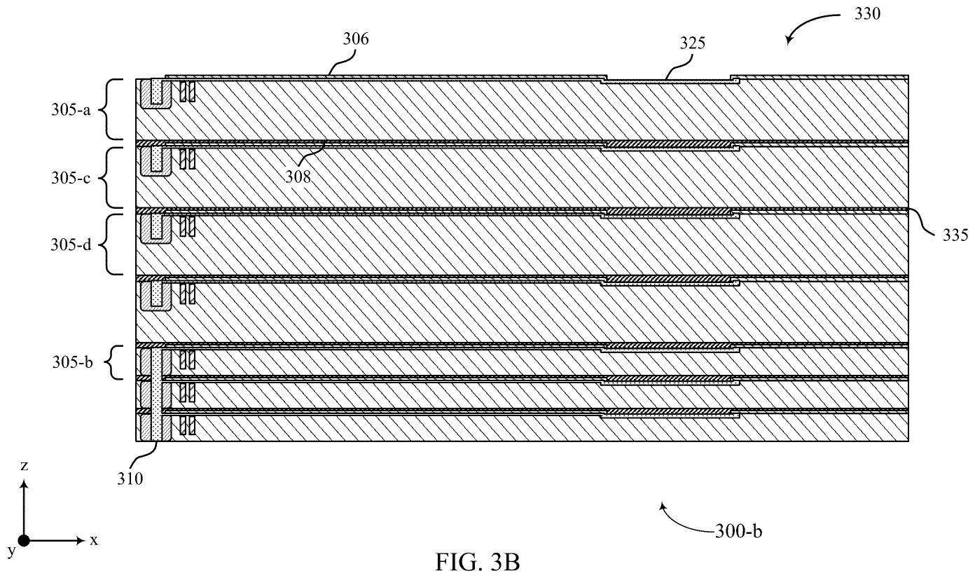

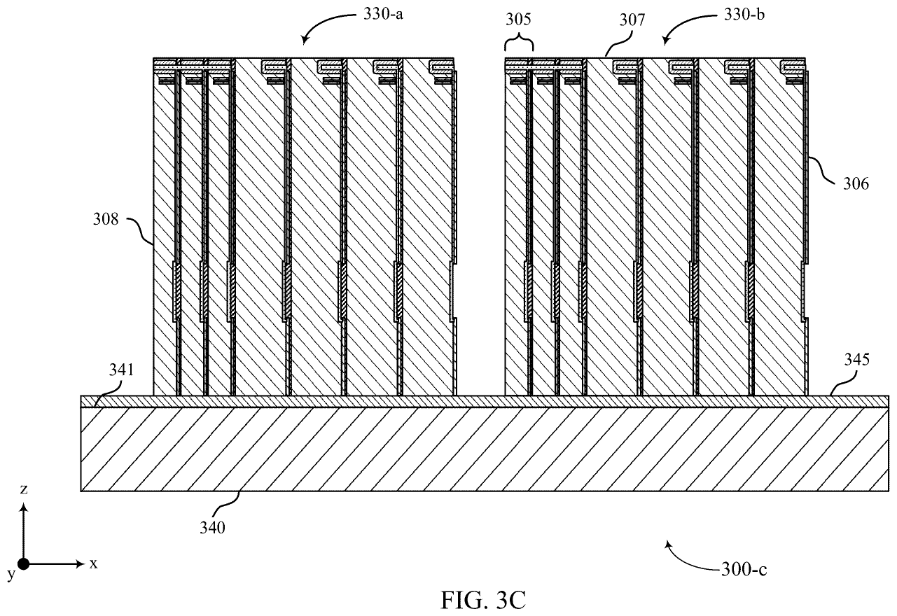

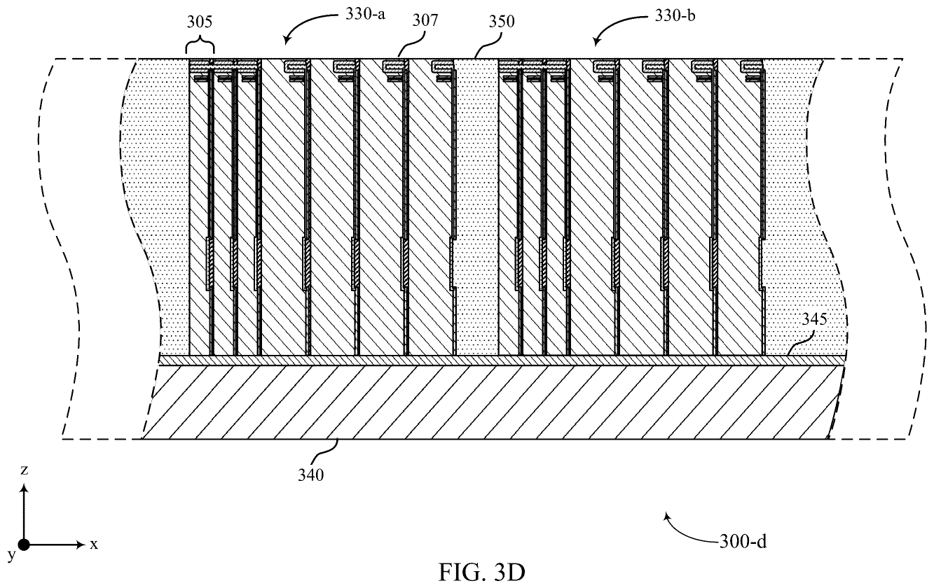

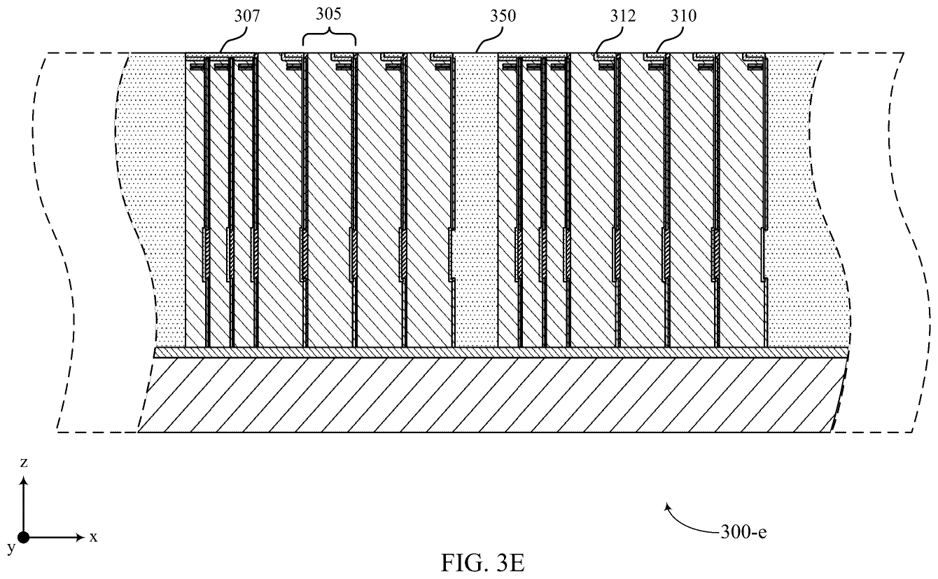

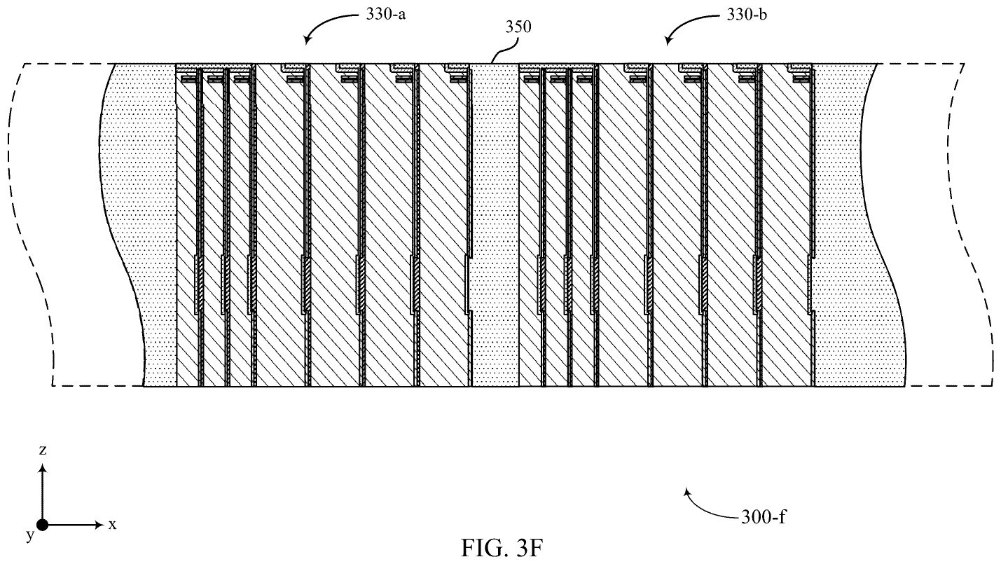

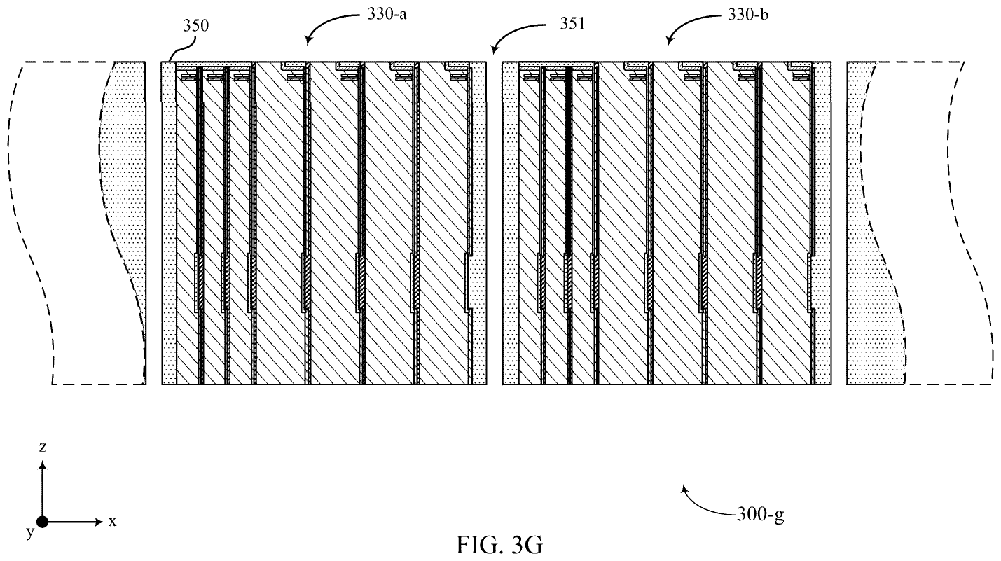

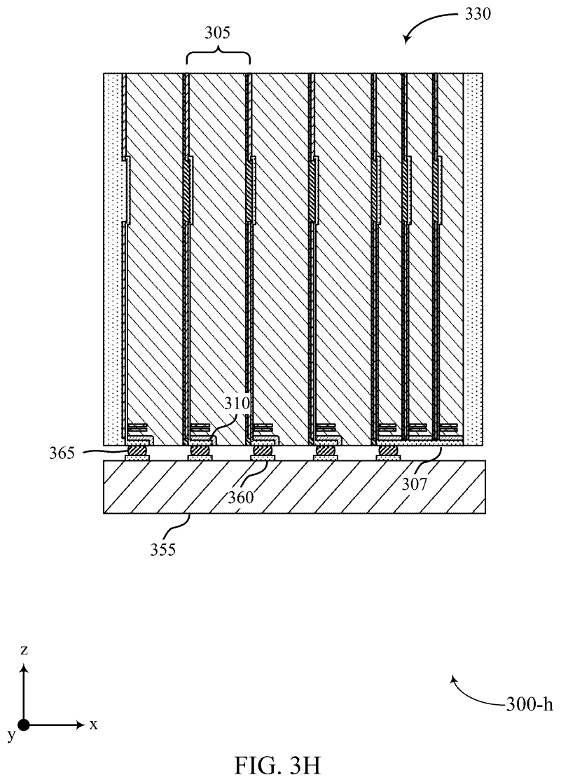

FIGS. 3A through 3H show examples of processing steps 300 that support die side interconnect in accordance with examples as disclosed herein. FIGS. 3A through 3H show various cross-sectional views of a semiconductor assembly, which may be an example of a semiconductor assembly 200, as described with reference to FIG. 2. Further, the processing steps 300 may illustrate aspects of manufacturing operations for fabricating aspects of a semiconductor assembly, which may be implemented in a system, such as a system 100, as described with reference to FIG. 1. The processing steps 300 may illustrate operations associated with implementing a stack 330 of dies 305 (e.g., first dies, memory dies) at a sideways orientation relative to a die 355 (e.g., a second die, a logic die).

For illustrative purposes, aspects of the semiconductor assembly may be described with reference to an x-direction, a y-direction, and a z-direction of the illustrated coordinate systems. For example, processing steps 300-a, 300-b, 300-c, 300-d, 300-c, 300-f, 300-g, and 300-h illustrate the semiconductor assembly from cross-sectional views in an xz-plane, where the semiconductor assembly extends a distance along the y-direction into the page. Although the processing steps 300 illustrate examples of relative dimensions and quantities of various features, aspects of the semiconductor assembly may be implemented with other relative dimensions or quantities of such features in accordance with examples as disclosed herein. In the following description of the processing steps 300, some methods, techniques, processes, and operations may be performed in different orders or at different times. Further, some operations may be left out of the processing steps 300, or other operations may be added to the processing steps 300.

Operations illustrated in and described with reference to FIGS. 3A through 3H may be performed by a manufacturing system, such as a semiconductor fabrication system configured to perform additive operations such as deposition, bonding, and/or coupling, subtractive operations such as etching, trenching, planarizing, and/or polishing, and supporting operations such as masking, patterning, photolithography, and/or aligning, among other operations that support the described techniques. In some examples, operations performed by such a manufacturing system may be supported by one or more controllers, such as one or more processors or processing circuitry, or its components as described herein.

FIG. 3A illustrates a processing step 300-a associated with forming dies 305, which may be an example of dies 210, as described with reference to FIG. 2. Forming the dies 305 may include forming different types of dies 305 (e.g., different types of memory dies). For example, forming a first type of die 305-a may include forming conductive vias 310 extending partially through a die 305-a from a top surface 306 of the die 305-a towards a bottom surface 308 of the die 305-a (e.g., as a TSV, as a via that does not extend through a wafer substrate of the die 305-a, as a via that extends partially through a wafer substrate of the die 305-a). Forming a second type of die 305-b may include forming the conductive vias 310 extending fully through the die 305-b from the top surface 306 to the bottom surface 308 of the die 305-b (e.g., as a TSV). The conductive vias 310 may be examples of the conductive vias 225, as described with reference to FIG. 2. For example, each die 305 may include one or more conductive vias 310 which may be vias extending perpendicular to the top surface 306 of the die 305. In some cases, the conductive vias 310 may be associated with (e.g., located in or adjacent to) a saw-street area 311 of the dies 305.

Forming the dies 305 may include forming a conductive via 310 extending through each die 305. In some cases, forming the conductive via 310 may include forming a dielectric layer 312 at least partially surrounding the conductive via 310, where the dielectric layer 312 may be an example of a dielectric layer 226, as described with reference to FIG. 2. For example, the dielectric layer 312 may surround the conductive via 310 of the first type of die 305-a on three sides of the conductive via 310, whereas the dielectric layer 312 may surround the conductive via 310 of the second type of die 305-b on two parallel sides of the conductive via 310. Forming the dies 305 may also include forming a conductive structure 315 within each die 305 adjacent to the dielectric layer 312, which may be an example of a conductive structure 245, as described with reference to FIG. 2.

Forming the dies 305 may also include forming redistribution layers 320 extending across the dies 305, which may be examples of redistribution layers 240, as described with reference to FIG. 2. For example, each die 305 may include a redistribution layer 320 extending along the top surface 306 of the die 305 in the x-direction. In some cases, the redistribution layer 320 may include a dielectric layer 321 partially covering the redistribution layer 320, which may be an example of a dielectric layer 241, as described with reference to FIG. 2. For example, forming the redistribution layer 320 may include forming the dielectric layer 321 above the redistribution layer 320 along the z-direction, such that a portion of the redistribution layer 320 may remain exposed after forming the dielectric layer 321. In some such examples, the exposed portion of the redistribution layer 320 may form a bond pad 325 for the die 305 (e.g., for bonding with other dies 305).

The processing step 300-a may be associated with dicing the dies 305. For example, the processing step 300-a may include cutting the dies 305 (e.g., from a wafer) in the saw-street areas along an yz-plane such that a portion of each die 305 is separated from the die 305. After the portion is separated, the portion may be discarded. In some cases, performing the dicing may include forming a trench 309 extending fully through each die 305.

FIG. 3B illustrates a processing step 300-b associated with forming a stack 330 of the dies 305. Forming the stack 330 may include bonding a quantity of the dies 305, such that top surfaces 306 are bonded with bottom surfaces 308 of the dies 305. For example, the top surface 306 of a die 305-c may be bonded with a bottom surface 308 of the die 305-a, and the bottom surface 308 of the die 305-c may be bonded with a top surface 306 of a die 305-d. In some cases, the dies 305 may include a bond film 335 on the top surface 306 of each die 305, which may be an example of a bond film 250, as described with reference to FIG. 2. For example, the stack 330 may include a bond film 335 on the top surface 306 of the die 305-c for bonding the top surface 306 of the die 305-c with the bottom surface 308 of the die 305-a. In some cases, bonding the dies 305 may include using the bond pads 325 for bonding the surfaces of the dies 305. For example, implementing the bond pads 325 and the bond film 335 may enable two adjacent dies 305 to be bonded.

In some cases, the stack 330 may include the different types of dies 305. For example, the stack 330 may include the first type of die 305-a (e.g., die 305-c, die 305-d), the second type of die 305-b, or any combination thereof. In some cases, the different types of dies 305 may also be associated with different functional circuitry configured for performing different operations, such that a first type of die 305 may be configured for first operations and a second type of die 305 may be configured for second operations (e.g., of a different type than the second operations). In some examples, implementing two or more adjacent dies 305 of the second type of die 305-b may form a single conductive via 310 extending through the two or more adjacent dies 305 (e.g., along the z-direction). For example, the stack 330 illustrates three adjacent dies 305 of the second type of die 305-b, which form a single conductive via 310 extending through the three adjacent dies 305. In some implementations, to facilitate forming the single conductive via 310, forming the stack 330 may include aligning the dies 305 along the x-direction.

FIG. 3C illustrates a processing step 300-c associated with rotating the stack 330. That is, the processing steps 300-a and 300-b may be associated with performing manufacturing processes on the semiconductor assembly when the dies 305 are positioned at a normal orientation (e.g., a 0° orientation, a horizontal orientation). For example, the stack 330 may be formed at processing step 300-b such that the top surfaces 306 of the dies 305 may be parallel to an xy-plane. However, the processing step 300-c may be associated with rotating the stack 330 such that the dies 305 are positioned at a sideways orientation (e.g., a 0° orientation, a vertical orientation). Positioning the stack 330 at the sideways orientation may cause the top surfaces 306 of the dies 305 to be parallel to a yz-plane or perpendicular to an xy-plane. That is, side surfaces 307 of the dies 305 may be parallel to an xy-plane.

In some cases, the processing step 300-c may include rotating multiple stacks 330 formed by the processing steps 300-a and 300-b. For example, the processing step 300-c illustrates rotating a stack 330-a and a stack 330-b to the sideways orientation. After rotating the stacks 330, the stacks 330 may be adhered to a carrier wafer 340. The carrier wafer 340 may be associated with maintaining the stacks 330 in fixed positions and orientations during other processing steps 300. In some cases, adhering the stacks 330 to the carrier wafer 340 may include applying an adhesive layer 345 to a top surface 341 of the carrier wafer 340 and depositing the stacks 330 onto the adhesive layer 345. The adhesive layer 345 may be associated with temporarily fixing the stacks 330 to the carrier wafer 340. In some cases, adhering the stacks 330 to the carrier wafer 340 may be based on rotating the stacks 330 to the sideways orientation, such that the stacks 330 may be adhered to the carrier wafer in the sideways orientation. For example, the side surfaces 307 of the dies 305 may be adhered to the top surface 341 of the carrier wafer 340. In some such examples, the side surfaces 307 of the dies 305 may be opposite to side surfaces 307 of the dies adjacent to the conductive vias 310.

FIG. 3D illustrates a processing step 300-d associated with forming an encapsulant material 350 surrounding the stacks 330. The processing step 300-d may include depositing the encapsulant material 350 adjacent to the stacks 330 in the x-direction and the y-direction. In some cases, the processing step 300-d may include depositing the encapsulant material 350 to the carrier wafer 340 or the adhesive layer 345 above the carrier wafer 340, along the z-direction, and depositing the encapsulant material 350 to a height coplanar with the side surfaces 307 of the dies 305. In some cases, the encapsulant material 350 may surround the stacks 330 and extend between the stacks as a result of the processing step 300-d. The encapsulant material 350 may be an example of the encapsulant material 220, as described with reference to FIG. 2.

FIG. 3E illustrates a processing step 300-e associated with exposing the conductive vias 310. The processing step 300-e may include removing portions of the dies 305 along the z-direction, such that the conductive vias 310 form the side surfaces 307 of the dies 305. In some cases, removing the portions of the dies 305 may include removing portions of the dielectric layer 312 surrounding the conductive vias 310. In some cases, removing the portions of the dies 305 may include grinding the side surfaces 307 of the dies 305, until the conductive vias 310 are coplanar with the side surfaces 307. In some such cases, grinding the side surfaces 307 may be performed using a planarization process. In some cases, exposing the conductive vias 310 may include removing portions of the encapsulant material 350 along the z-direction, such that the encapsulant material 350 is coplanar with the sides surfaces 307 of the dies 305.

FIG. 3F illustrates a processing step 300-f associated with removing the carrier wafer 340. That is, the processing step 300-f may include removing the carrier wafer 340 from the stacks 330. In some cases, removing the carrier wafer 340 from the stacks 330 may include separating the stacks 330 from the adhesive layer 345 associated with the carrier wafer 340. For example, the stacks 330 may be released from the adhesive layer 345 and remaining portions of the adhesive layer clinging to the stacks 330 may be removed. Removing the carrier wafer 340 may not remove the encapsulant material 350 between and surrounding the stacks 330.

FIG. 3G illustrates a processing step 300-g associated with separating the stacks 330. The processing step 300-g may include separating the stack 330-a and the stack 330-b such that the stacks 330 are individually packaged. In some cases, separating the stacks 330 may include dicing through the encapsulant material 350, such that each stack 330 has a layer of the encapsulant material 350 surrounding the stack 330. In some such cases, the processing step 300-g may include cutting the encapsulant material 350 along an yz-plane such that layers of the encapsulant material 350 are adjacent to the stack 330 along the x-direction. In some cases, performing the dicing may include forming trenches 351 extending fully through the encapsulant material 350. In some cases, dicing the stacks 330 may include placing the stacks 330 on a dicing film, such that the trenches 351 may be formed by cutting the encapsulant material 350 down (e.g., in the z-direction) to the dicing film.

FIG. 3H illustrates a processing step 300-h associated with bonding the stack 330 with a die 355 (e.g., a logic die), which may be an example of a die 215, as described with reference to FIG. 2. After separating the stack 330, the stack 330 may be bonded with the die 355 such that the stack 330 is positioned at the sideways orientation relative to the die 355. That is, the side surfaces 307 of the dies 305 may be bonded with a top surface 356 of the die 355 to couple the dies 305 with the die 355. The processing step 300-h may include bonding the conductive vias 310 with bond pads 360 of the die 355, which may be examples of bond pads 230, as described with reference to FIG. 2. In some cases, the conductive vias 310 may be hybrid bonded with the bond pads 360. In other cases, interconnects 365 may be formed between the conductive vias 310 and the bond pads 360, which may be examples of interconnects 235, as described with reference to FIG. 2. For example, the interconnects 365 may be solder or optical elements extending between the conductive vias 310 and the bond pads 360.

In accordance with examples as described herein, implementing the processing steps 300 may form a semiconductor assembly with the stack 330 of dies 305 at the sideways orientation relative to the die 355. Implementing the stack 330 at the sideways orientation may support improved connectivity between the dies 305 and the die 355. For example, using the conductive vias 310 for bonding the dies 305 with the die 355 may enable the redistribution layers 320 to function as conductive vias extending through the dies 305. In some such examples, the redistribution layers 320 may support increased data path connectivity, improved heat dissipation through the stack 330, and improved power delivery from the die 355.

In some cases, the processing steps 300 may be implemented in another order, excluding one or more of the processing steps 300. For example, prior to forming the stacks 330, the dies 305 may be diced through the conductive vias 310, such that the conductive vias 310 may be exposed at the processing step 300-a (e.g., rather than at the processing step 300-c). Then, the dies 305 may be aligned and bonded to form the stacks 330. However, based on exposing the conductive vias 310 at the processing step 300-a, the processing step 300-c may be excluded from the processing steps 300. Implementing the processing steps 300 in such an order may form the semiconductor assembly such that similar benefits may be achieved.

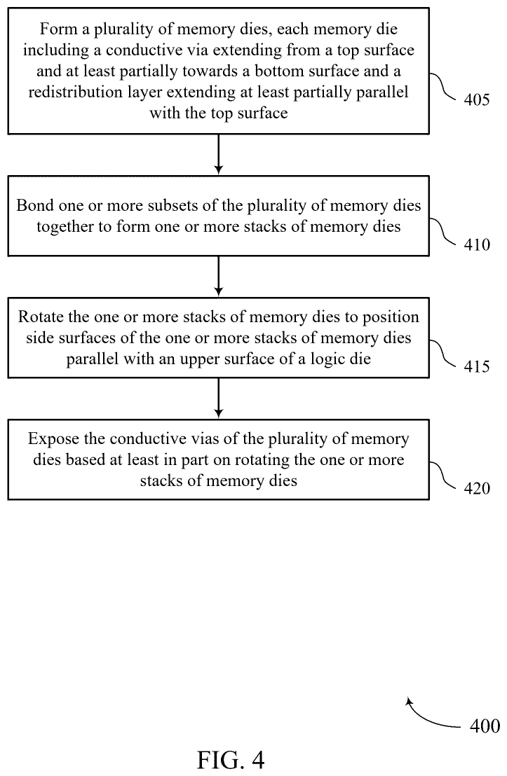

FIG. 4 shows a flowchart illustrating a method or methods 400 that support die side interconnect in accordance with examples as disclosed herein. The operations of method 400 may be implemented by a manufacturing system or one or more controllers associated with a manufacturing system, its components as described herein. In some examples, one or more controllers may execute a set of instructions to control one or more functional elements of the manufacturing system to perform the described functions. Additionally, or alternatively, one or more controllers may perform aspects of the described functions using special-purpose hardware.

At 405, the method may include forming a plurality of memory dies, each memory die including a conductive via extending from a top surface and at least partially towards a bottom surface and a redistribution layer extending at least partially parallel with the top surface.

At 410, the method may include bonding one or more subsets of the plurality of memory dies together to form one or more stacks of memory dies.

At 415, the method may include rotating the one or more stacks of memory dies to position side surfaces of the one or more stacks of memory dies parallel with an upper surface of a logic die.

At 420, the method may include exposing the conductive vias of the plurality of memory dies based at least in part on rotating the one or more stacks of memory dies.

In some examples, an apparatus (e.g., a manufacturing system) as described herein may perform a method or methods, such as the method 400. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:
Aspect 1: A method or apparatus including operations, features, circuitry, logic, means, or instructions, or any combination thereof for forming a plurality of memory dies, each memory die including a conductive via extending from a top surface and at least partially towards a bottom surface and a redistribution layer extending at least partially parallel with the top surface; bonding one or more subsets of the plurality of memory dies together to form one or more stacks of memory dies; rotating the one or more stacks of memory dies to position side surfaces of the one or more stacks of memory dies parallel with an upper surface of a logic die; and exposing the conductive vias of the plurality of memory dies based at least in part on rotating the one or more stacks of memory dies.
Aspect 2: The method or apparatus of aspect 1, further including operations, features, circuitry, logic, means, or instructions, or any combination thereof for forming encapsulant material at least partially surrounding the one or more stacks of memory dies based at least in part on rotating the one or more stacks of memory dies.
Aspect 3: The method or apparatus of aspect 2, where exposing the conductive vias includes operations, features, circuitry, logic, means, or instructions, or any combination thereof for planarizing the encapsulant material and the one or more stacks of memory dies and where planarizing the encapsulant material includes removing a portion of the encapsulant material and a portion of each memory die.
Aspect 4: The method or apparatus of any of aspects 1 through 3, further including operations, features, circuitry, logic, means, or instructions, or any combination thereof for bonding the one or more stacks of memory dies with the logic die based at least in part on bonding the side surfaces of the plurality of memory dies with the upper surface of the logic die.
Aspect 5: The method or apparatus of any of aspects 1 through 4, further including operations, features, circuitry, logic, means, or instructions, or any combination thereof for dicing the one or more stacks of memory dies based at least in part on exposing the conductive vias of the plurality of memory dies, where dicing the one or more stacks of memory dies includes separating the one or more stacks of memory dies.
Aspect 6: The method or apparatus of any of aspects 1 through 5, further including operations, features, circuitry, logic, means, or instructions, or any combination thereof for adhering the one or more stacks of memory dies to a carrier wafer, where the side surfaces of the plurality of memory dies are adhered to a top surface of the carrier wafer based at least in part on rotating the one or more stacks of memory dies.
Aspect 7: The method or apparatus of aspect 6, further including operations, features, circuitry, logic, means, or instructions, or any combination thereof for removing the carrier wafer from the one or more stacks of memory dies based at least in part on adhering the one or more stacks of memory dies to the carrier wafer.
Aspect 8: The method or apparatus of any of aspects 1 through 7, where bonding the one or more subsets of the plurality of memory dies includes operations, features, circuitry, logic, means, or instructions, or any combination thereof for bonding a respective top surface of a first memory die with a respective bottom surface of a second memory die.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:
Aspect 9: A semiconductor device assembly, including: a logic die including an upper surface; and a stack of memory dies including a first memory die and a second memory die, the first memory die having a top surface that is coupled with a bottom surface of the second memory die to form the stack, the first memory die and the second memory die each having a respective side surface coupled with the upper surface of the logic die, where each of the first memory die and the second memory die includes: a conductive via extending from the top surface and at least partially through towards the bottom surface; and a redistribution layer coupled with the conductive via and extending at least partially parallel with the top surface.
Aspect 10: The semiconductor device assembly of aspect 9, where the logic die includes one or more bond pads on the upper surface of the logic die, and each of the first memory die and the second memory die includes one or more bond pads on the respective side surface formed by the conductive via.
Aspect 11: The semiconductor device assembly of aspect 10, where the stack of memory dies are coupled with the logic die based at least in part on the one or more bond pads on the upper surface of the logic die being hybrid bonded with the one or more bond pads on the respective side surfaces of the first memory die and the second memory die.
Aspect 12: The semiconductor device assembly of any of aspects 10 through 11, further including: a plurality of interconnects extending between the one or more bond pads on the upper surface of the logic die and the one or more bond pads on the respective side surfaces of the first memory die and the second memory die, where the stack of memory dies are coupled with the logic die based at least in part on the plurality of interconnects.
Aspect 13: The semiconductor device assembly of aspect 12, where the plurality of interconnects each include: a solder ball including copper, nickel, tin, silver, indium, or any combination thereof.
Aspect 14: The semiconductor device assembly of any of aspects 12 through 13, where the plurality of interconnects each include an optical element.
Aspect 15: The semiconductor device assembly of any of aspects 9 through 14, where each of the first memory die and the second memory die further includes: a dielectric layer on the top surface, where the dielectric layer at least partially covers the redistribution layer.
Aspect 16: The semiconductor device assembly of aspect 15, where the dielectric layer includes a tetraethyl orthosilicate material, an oxide material, or a silicon carbon nitride material.
Aspect 17: The semiconductor device assembly of any of aspects 9 through 16, where the stack of memory dies further includes: a plurality of bond films extending along the top surface of the first memory die and the top surface of the second memory die.
Aspect 18: The semiconductor device assembly of any of aspects 9 through 17, where each of the first memory die and the second memory die further includes: a conductive structure extending from the top surface and at least partially towards the bottom surface, where the conductive structure is adjacent to the conductive via.
Aspect 19: The semiconductor device assembly of aspect 18, where the conductive structure includes a tungsten wall.
Aspect 20: The semiconductor device assembly of any of aspects 9 through 19, where each memory die further includes: a dielectric layer at least partially surrounding the conductive via.
Aspect 21: The semiconductor device assembly of any of aspects 9 through 20, where: the logic die includes a complementary metal oxide semiconductor or one or more processors, or both; and each memory die includes one or more memory arrays.
Aspect 22: The semiconductor device assembly of any of aspects 9 through 21, where the stack of memory dies includes one or more of a first type of memory die and one or more of a second type of memory die.
Aspect 23: The semiconductor device assembly of aspect 22, where: a memory die of the first type of memory die includes the conductive via extending from the top surface to the bottom surface; and a memory die of the second type of memory die includes the conductive via extending from the top surface and partially through the memory die.
Aspect 24: The semiconductor device assembly of any of aspects 9 through 23, where the conductive via and the redistribution layer each include a copper material, a tungsten material, an aluminum material, or any combination thereof.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “isolated” may refer to a relationship between components in which signals are not presently capable of flowing between the components. Components are isolated from each other if there is an open circuit between them. For example, two components separated by a switch that is positioned between the components are isolated from each other when the switch is open. When a component isolates two components, the component may initiate a change that prevents signals from flowing between the other components using a conductive path that previously permitted signals to flow.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component may initiate a change that allows signals to flow between the other components over a conductive path that previously did not permit signals to flow.

The terms “layer” and “level” may refer to an organization (e.g., a stratum, a sheet) of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials. In some examples, one layer or level may be composed of two or more sublayers or sublevels.

As used herein, the term “electrode” may refer to an electrical conductor, and in some examples, may be employed as an electrical contact to a memory cell or other component of a memory array. An electrode may include a trace, a wire, a conductive line, a conductive layer, or the like that provides a conductive path between components of a memory array.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOS), or epitaxial layers of semiconductor materials on another substrate. The conductivity of the substrate, or sub-regions of the substrate, may be controlled through doping using various chemical species including, but not limited to, phosphorous, boron, or arsenic.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A semiconductor device assembly, comprising:
a logic die comprising an upper surface; and
a stack of memory dies comprising a first memory die and a second memory die, the first memory die having a top surface that is coupled with a bottom surface of the second memory die to form the stack, the first memory die and the second memory die each having a respective side surface coupled with the upper surface of the logic die, wherein each of the first memory die and the second memory die comprises:
a conductive via extending from the top surface and at least partially through towards the bottom surface; and
a redistribution layer coupled with the conductive via and extending at least partially parallel with the top surface.

2. The semiconductor device assembly of claim 1, wherein the logic die comprises one or more bond pads on the upper surface of the logic die, and each of the first memory die and the second memory die comprises one or more bond pads on the respective side surface formed by the conductive via.

3. The semiconductor device assembly of claim 2, wherein the stack of memory dies are coupled with the logic die based at least in part on the one or more bond pads on the upper surface of the logic die being hybrid bonded with the one or more bond pads on the respective side surfaces of the first memory die and the second memory die.

4. The semiconductor device assembly of claim 2, further comprising:
a plurality of interconnects extending between the one or more bond pads on the upper surface of the logic die and the one or more bond pads on the respective side surfaces of the first memory die and the second memory die,
wherein the stack of memory dies are coupled with the logic die based at least in part on the plurality of interconnects.

5. The semiconductor device assembly of claim 4, wherein the plurality of interconnects each comprise:
a solder ball comprising copper, nickel, tin, silver, indium, or any combination thereof.

6. The semiconductor device assembly of claim 4, wherein the plurality of interconnects each comprise an optical element.

7. The semiconductor device assembly of claim 1, wherein each of the first memory die and the second memory die further comprises:
a dielectric layer on the top surface,
wherein the dielectric layer at least partially covers the redistribution layer.

8. The semiconductor device assembly of claim 7, wherein the dielectric layer comprises a tetraethyl orthosilicate material, an oxide material, or a silicon carbon nitride material.

9. The semiconductor device assembly of claim 1, wherein the stack of memory dies further comprises:
a plurality of bond films extending along the top surface of the first memory die and the top surface of the second memory die.

10. The semiconductor device assembly of claim 1, wherein each of the first memory die and the second memory die further comprises:
a conductive structure extending from the top surface and at least partially towards the bottom surface, wherein the conductive structure is adjacent to the conductive via.

11. The semiconductor device assembly of claim 10, wherein the conductive structure comprises a tungsten wall.

12. The semiconductor device assembly of claim 1, wherein each memory die further comprises:
a dielectric layer at least partially surrounding the conductive via.

13. The semiconductor device assembly of claim 1, wherein:
the logic die comprises a complementary metal oxide semiconductor or one or more processors, or both; and
each memory die comprises one or more memory arrays.

14. The semiconductor device assembly of claim 1, wherein the stack of memory dies comprises one or more of a first type of memory die and one or more of a second type of memory die.

15. The semiconductor device assembly of claim 14, wherein:
a memory die of the first type of memory die comprises the conductive via extending from the top surface to the bottom surface; and
a memory die of the second type of memory die comprises the conductive via extending from the top surface and partially through the memory die.

16. The semiconductor device assembly of claim 1, wherein the conductive via and the redistribution layer each comprise a copper material, a tungsten material, an aluminum material, or any combination thereof.

17. A method of manufacturing a semiconductor device assembly, comprising:
forming a plurality of memory dies, each memory die comprising a conductive via extending from a top surface and at least partially towards a bottom surface and a redistribution layer extending at least partially parallel with the top surface;
bonding one or more subsets of the plurality of memory dies together to form one or more stacks of memory dies;
rotating the one or more stacks of memory dies to position side surfaces of the one or more stacks of memory dies parallel with an upper surface of a logic die; and
exposing the conductive vias of the plurality of memory dies based at least in part on rotating the one or more stacks of memory dies.

18. The method of claim 17, further comprising:
forming encapsulant material at least partially surrounding the one or more stacks of memory dies based at least in part on rotating the one or more stacks of memory dies.

19. The method of claim 18, wherein exposing the conductive vias comprises:
planarizing the encapsulant material and the one or more stacks of memory dies,
wherein planarizing the encapsulant material comprises removing a portion of the encapsulant material and a portion of each memory die.

20. The method of claim 17, further comprising:
bonding the one or more stacks of memory dies with the logic die based at least in part on bonding the side surfaces of the plurality of memory dies with the upper surface of the logic die.

21. The method of claim 17, further comprising:
dicing the one or more stacks of memory dies based at least in part on exposing the conductive vias of memory dies, wherein dicing the one or more stacks of memory dies comprises separating the one or more stacks of memory dies.

22. The method of claim 17, further comprising:
adhering the one or more stacks of memory dies to a carrier wafer, wherein the side surfaces of the plurality of memory dies are adhered to a top surface of the carrier wafer based at least in part on rotating the one or more stacks of memory dies.

23. The method of claim 22, further comprising:
removing the carrier wafer from the one or more stacks of memory dies based at least in part on adhering the one or more stacks of memory dies to the carrier wafer.

24. The method of claim 17, wherein bonding the one or more subsets of the plurality of memory dies comprises:
bonding a respective top surface of a first memory die with a respective bottom surface of a second memory die.
